(19) United States
(12) Patent Application Publication
(10) Pub. No.: US 2004/0040660 A1
(43) Pub. Date: Mar. 4, 2004

(54) High pressure processing chamber for multiple semiconductor substrates

(76) Inventors: Maximilian Albert Biberger, Palo Alto, CA (US); Frederick Paul Layman, Fremont, CA (US)

Correspondence Address: Thomas B. Haverstock, HAVERSTOCK & OWENS LLP, Suite 420, 260 Sheridan Avenue, Palo Alto, CA, 94306, US

(21) Appl. No.: 09/970,309

(22) Filed: Oct. 3, 2001

(51) Int. Cl. H01L 21/306

(52) U.S. Cl. 156/345.31; 118/733

(57) ABSTRACT

A high pressure processing chamber for processing multiple semiconductor substrates comprises a chamber housing, a cassette, and a chamber closure. The cassette is removably coupled to the chamber housing. The cassette is configured to accommodate at least two semiconductor substrates. The chamber closure is coupled to the chamber housing. The chamber closure is configured such that in operation the chamber closure seals with the chamber housing to provide an enclosure for high pressure processing of the semiconductor substrates.

### FIELD OF THE INVENTION

This invention relates to the field of high pressure processing chambers for semiconductor substrates. More particularly, this invention relates to the field of high pressure processing chambers for semiconductor substrates where a high pressure processing chamber provides processing capability for simultaneous processing of multiple semiconductor substrates.

### BACKGROUND OF THE INVENTION

Recently, interest has developed in supercritical processing for semiconductor substrates for such processes as photoresist removal, rinse agent drying, and photoresist development. The supercritical processing is a high pressure processing where pressure and temperature are at or above a critical pressure and a critical temperature. Above the critical temperature and the critical pressure, there is no liquid or gas phase. Instead, there is a supercritical phase.

A typical semiconductor substrate is a semiconductor wafer. The semiconductor wafer has a thin cross-section and a large diameter. Currently, semiconductor wafers have diameters up to 300 mm. Because of a capital outlay for both semiconductor development and for semiconductor processing equipment, semiconductor processing must be efficient, reliable, and economical.

Thus, a supercritical processing system intended for semiconductor processing of multiple semiconductor substrates must have a high pressure processing chamber which is efficient, reliable, and economical.

What is needed is a high pressure processing chamber for processing multiple semiconductor substrates which is efficient, reliable, and economical.

### SUMMARY OF THE INVENTION

The present invention is a high pressure processing chamber for processing multiple semiconductor substrates. The high pressure processing chamber comprises a chamber housing, a cassette, and a chamber closure. The cassette is removably coupled to the chamber housing. The cassette is configured to accommodate at least two semiconductor substrates. The chamber closure is coupled to the chamber housing. The chamber closure is configured such that in operation the chamber closure seals with the chamber housing to provide an enclosure for high pressure processing of the semiconductor substrates.

### BRIEF DESCRIPTION OF THE DRAWINGS

FIG. 1 illustrates the preferred high pressure processing chamber and a lifting mechanism of the present invention.

FIGS. 2A and 2B illustrate a locking ring of the present invention.

FIG. 3 further illustrates the preferred high pressure processing chamber of the present invention.

FIG. 4 illustrates the preferred cassette of the present invention.

FIGS. 5A and 5B illustrate a chamber housing, first and second cassettes, and a 15′ robot of the present invention.

FIGS. 6A and 6B illustrate an injection nozzle arrangement and a fluid outlet arrangement of the present invention.

FIG. 7 illustrates a supercritical processing system of the present invention.

FIG. 8 illustrates a first alternative high pressure processing chamber of the present invention.

FIG. 9 illustrates a first alternative cassette of the present invention.

FIG. 10 illustrates a second alternative cassette of the present invention.

### DETAILED DESCRIPTION OF THE PREFERRED EMBODIMENT

Preferably, the preferred high pressure processing chamber of the present invention simultaneously processes multiple semiconductor substrates. Preferably, the semiconductor substrates comprise semiconductor wafers. Alternatively, the semiconductor substrates comprise other semiconductor substrates such as semiconductor pucks. Further alternatively, the semiconductor substrates comprise trays with each tray capable of holding multiple semiconductor devices.

Preferably, the preferred high pressure processing chamber of the present invention provides a supercritical processing environment. More preferably, the preferred high pressure processing chamber provides a supercritical CO₂ processing environment. Preferably, the supercritical CO₂ processing environment comprises a drying environment for drying developed photoresist which has been rinsed but not dried. Alternatively, the supercritical CO₂ processing environment comprises an alternative drying environment for other semiconductor drying processes such as drying MEMS devices. Alternatively, the supercritical CO₂ processing environment comprises a photoresist development environment. Further alternatively, the supercritical CO₂ processing environment comprises a semiconductor cleaning environment, for example, for a photoresist and residue cleaning or for a CMP (chemical mechanical planarization) residue cleaning.

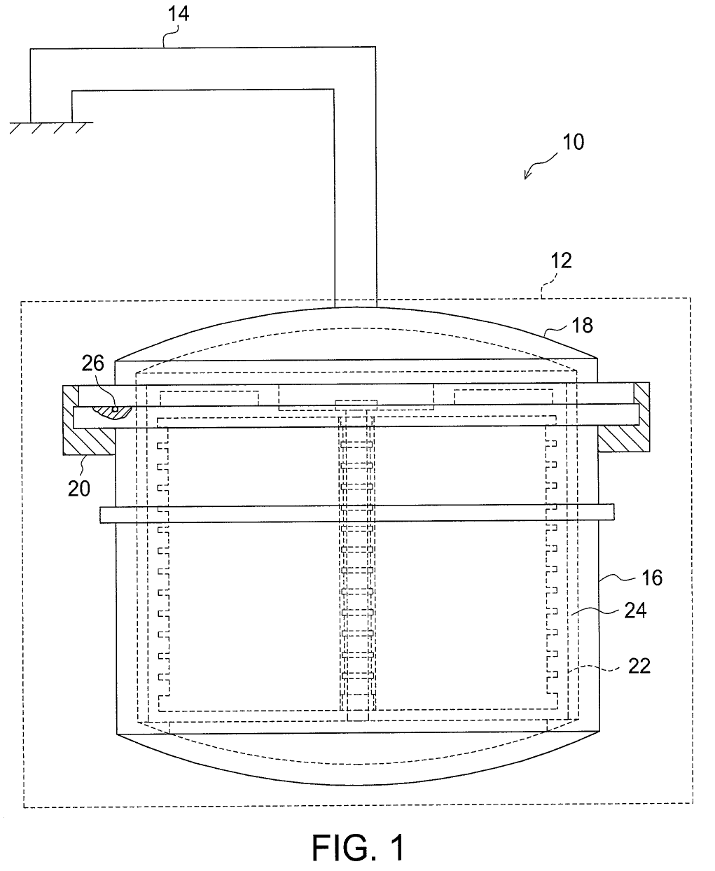

A high pressure processing chamber assembly of the present invention is illustrated in FIG. 1. The high pressure processing chamber assembly 10 comprises the preferred high pressure processing chamber 12 and a lid lifting mechanism 14. The preferred high pressure processing chamber 12 comprises a chamber housing 16, a chamber lid 18, a locking ring 20, a preferred cassette 22, and a first o-ring seal 26. Preferably, the chamber housing 16 and the chamber lid 18 comprise stainless steel. Preferably, the locking ring 20 comprises high tensile strength steel. Preferably, the preferred cassette 22 comprises stainless steel. Alternatively, the preferred cassette 22 comprises a corrosion resistant metal. Further alternatively, the preferred cassette 22 comprises a corrosion resistant polymer material.

The lid lifting mechanism 14 couples to the chamber lid 18. The locking ring 20 couples to the chamber housing 16. When the preferred high pressure processing chamber 12 is closed, the locking ring 20 couples the chamber housing 16 to the chamber lid 18 to form a processing enclosure 24. The preferred cassette 22 couples to an interior of the chamber housing 16.

In use, the locking ring 20 locks the chamber lid 18 to the chamber housing 16. The locking ring 20 also maintains a sealing force between the chamber lid 18 and the chamber housing 16 to preclude high pressure fluid within the processing enclosure 24 from leaking past the first o-ring seal 26. When the locking ring 20 is disengaged from the chamber lid 18, the lid lifting mechanism 14 raises the lid 18 and swings the lid 18 away from the chamber housing 16.

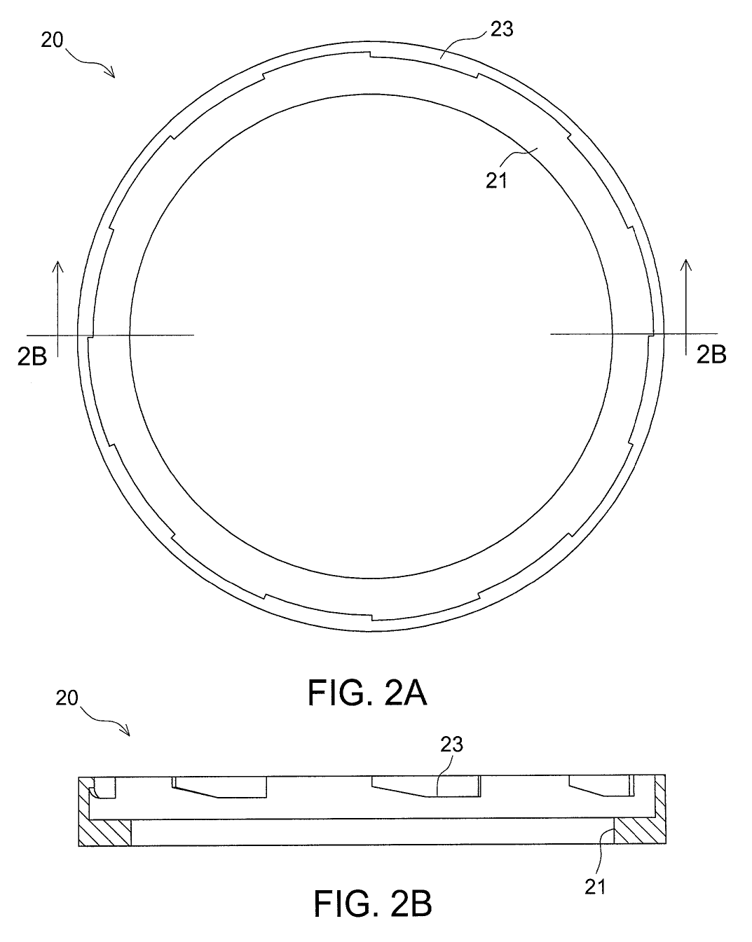

The locking ring 20 of the present invention is further illustrated in FIGS. 2A and 2B. The locking ring 20 comprises a broken thread and a lip 21. The broken thread comprises mating surfaces 23, which mate to corresponding features on the chamber housing 16 (FIG. 1).

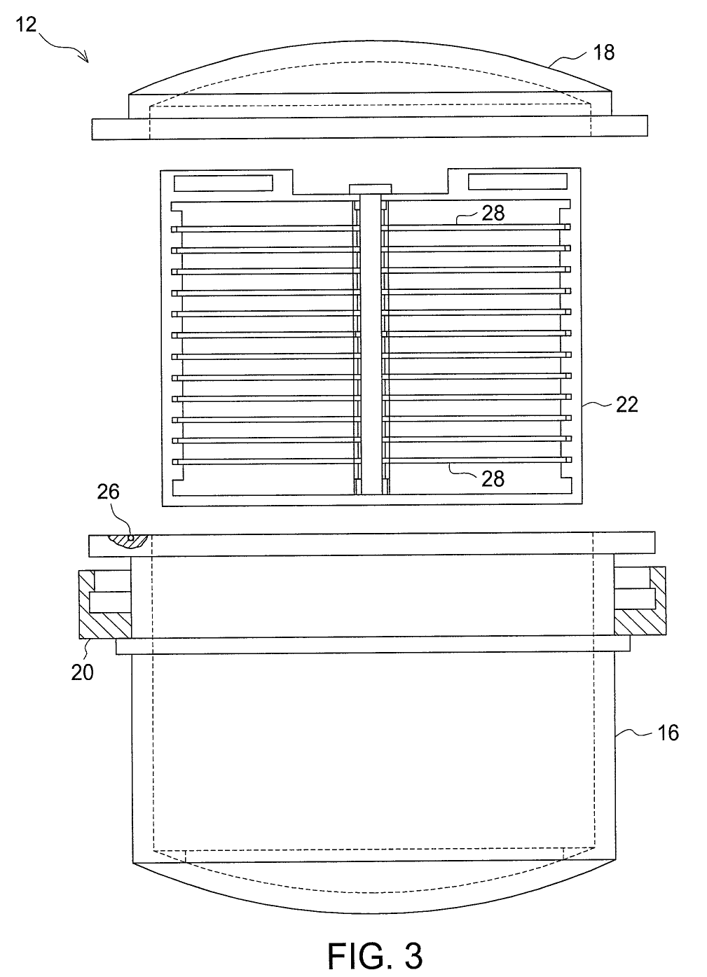

The high pressure processing chamber 10 is further illustrated in FIG. 3. In operation, the preferred cassette 22 preferably holds semiconductor wafers 28. A robot (not shown) preferably loads the preferred cassette 22 into the chamber housing 16 and retracts. The lid lifting mechanism 14 (FIG. 1) then lowers the chamber lid 18 onto the chamber housing 16. Following this, the locking ring 20 locks and seals the chamber lid 18 to the chamber housing 16. Subsequently, the semiconductor wafers are preferably processed in the supercritical environment. Next, the lid lifting mechanism 14 raises the chamber lid 18. Finally, the robot removes the preferred cassette 22 from the chamber housing 16.

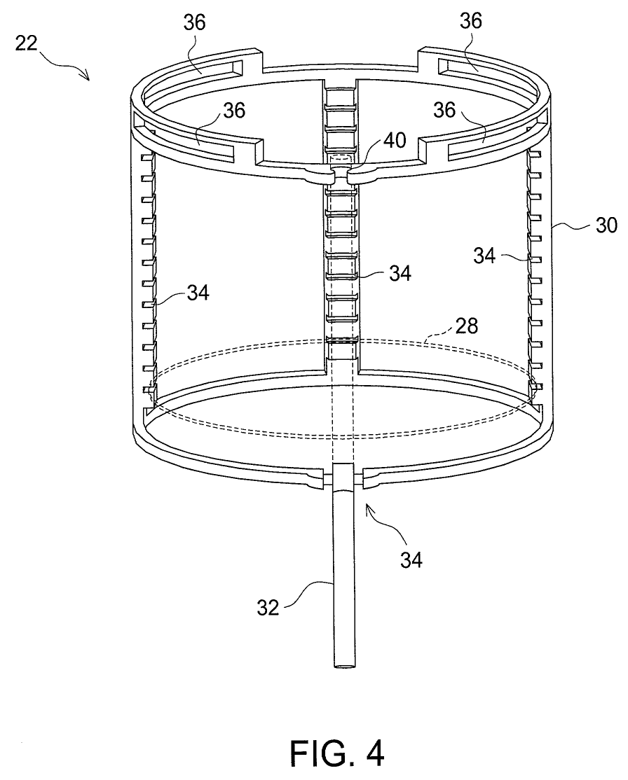

The preferred cassette 22 of the present invention is further illustrated in FIG. 4.

The preferred cassette 22 comprises a cassette frame 30 and a retaining bar 32. The cassette frame 30 comprises wafer holding slots 34, and lifting features 36. Preferably, the retaining bar 32 is coupled to the cassette frame 30 via a hinge 38. Preferably, in use, the semiconductor wafers 28 (one shown with dashes lines) are loaded into the preferred cassette 22. More preferably, the semiconductor wafers are loaded into the preferred cassette 22 by a transfer of the semiconductor wafers 28 from a FOUP (front opening unified pod) to preferred cassette 22. Once the semiconductor wafers 28 are loaded into the preferred cassette 22, the retaining bar 32 is preferably snapped into a retaining slot 40 in the cassette frame 30.

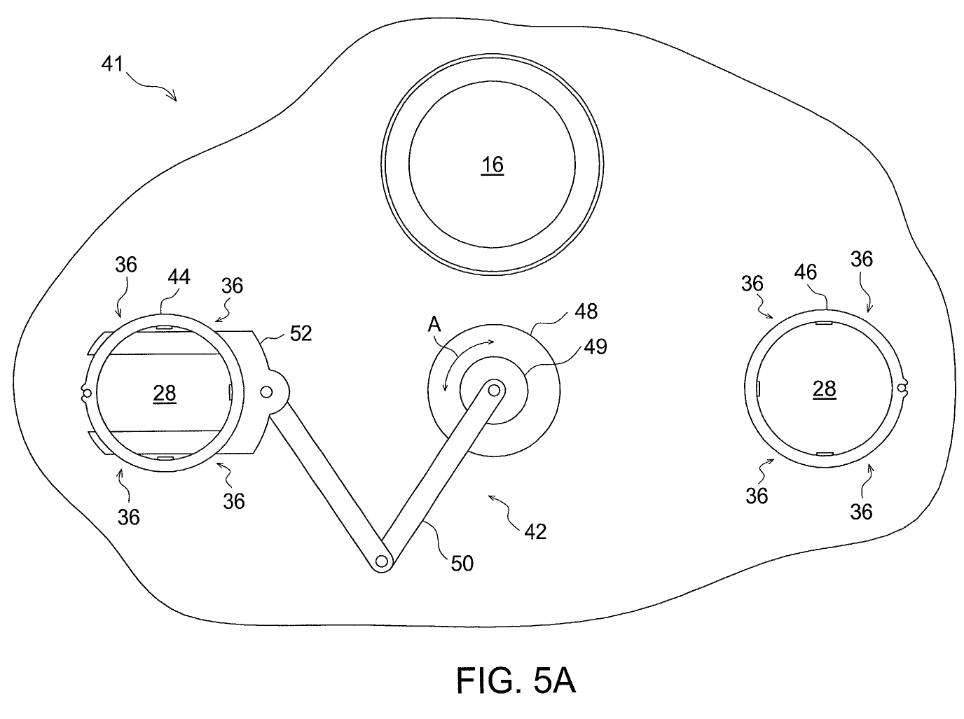

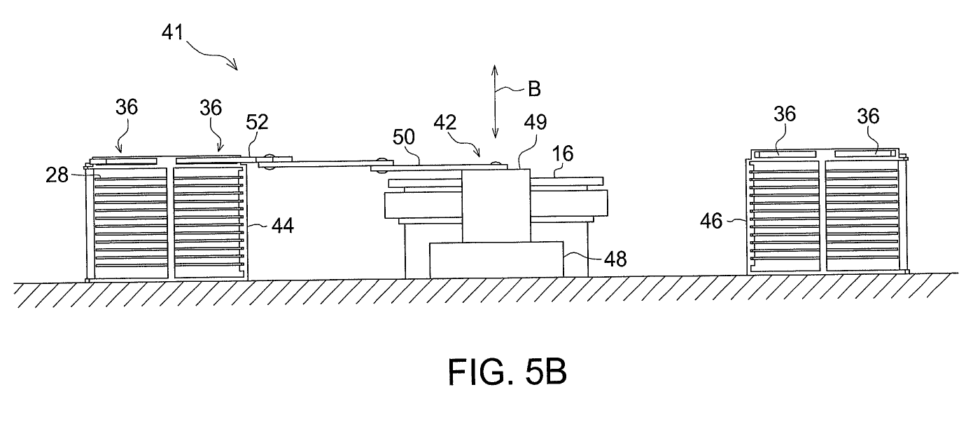

An automated processing arrangement of the present invention is illustrated in FIGS. 5A and 5B. The automated processing arrangement 41 comprises the chamber housing 16, the robot 42, and first and second cassettes, 44 and 46. The robot 42 comprises a robot base 48, a vertical motion unit 49, a robot arm 50, and a forked cassette interface 52. The robot base 48 provides a rotation movement A for the robot arm 50. The vertical motion unit 49 provides a vertical movement B for the robot arm 50. Prior to processing, the first and second cassettes, 44 and 46, are loaded with the semiconductor wafers 28. In operation, the robot arm 50 extends the forked cassette interface 52 through the lifting features 36 of the first cassette 44, lifts the first cassette 44, moves the first cassette 44 to a position above the chamber housing 16, lowers the first cassette into the chamber housing 16, and retracts the forked cassette interface 52. Following this, the semiconductor wafers 28 in the first cassette 44 are processed. Next, the robot 42 extends the forked cassette interface 52 through the lifting features 36 of the first cassette 44 and removes the first cassette 44 from the chamber housing 16. Subsequently, the robot 42 handles the second cassette 46 holding more of the semiconductor wafers 28 in a similar fashion to the handling of the first cassette 44.

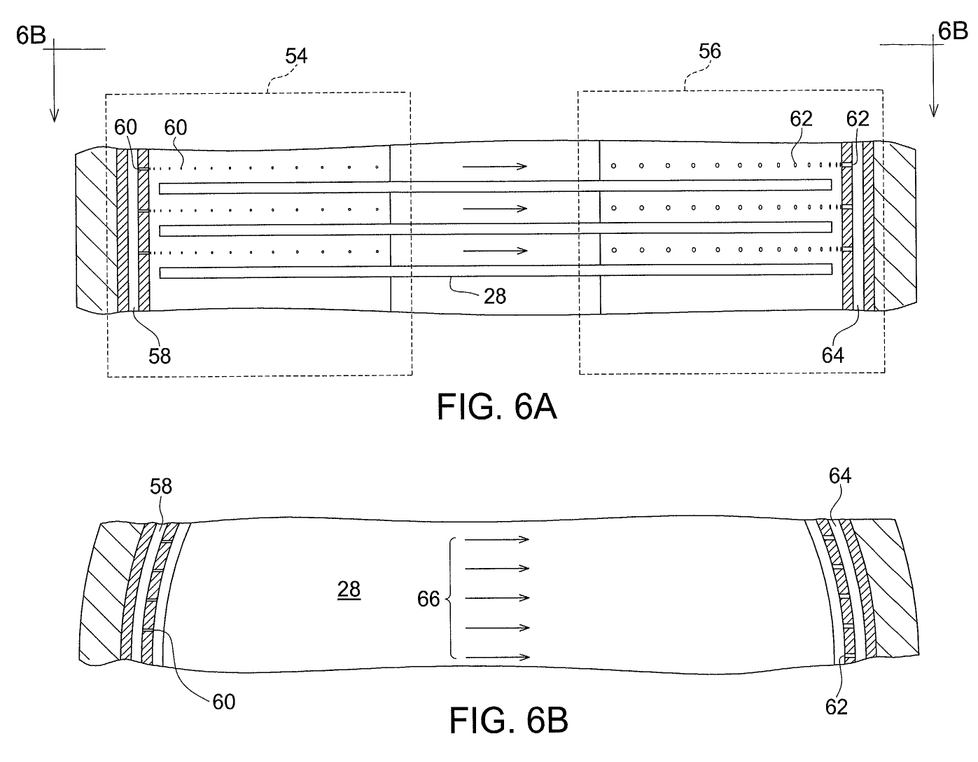

An injection nozzle arrangement and a fluid outlet arrangement of the present invention is illustrated in FIGS. 6A and 6B. Preferably, the injection nozzle arrangement 54 and fluid outlet arrangement 56 are located within the chamber housing 16.

Alternatively, the injection nozzle arrangement 54 forms part of the preferred cassette 22 (FIG. 4). Further alternatively, the fluid outlet arrangement 56 forms part of the preferred cassette 22 (FIG. 4). The injection nozzle arrangement 54 comprises a reservoir 58 and injection nozzles 60. The fluid outlet arrangement 56 comprises fluid outlets 62 and a drain 64. In operation, the injection nozzle arrangement 54 and the fluid outlet arrangement 56 work in conjunction to provide a processing fluid flow 66 across the semiconductor wafers 28.

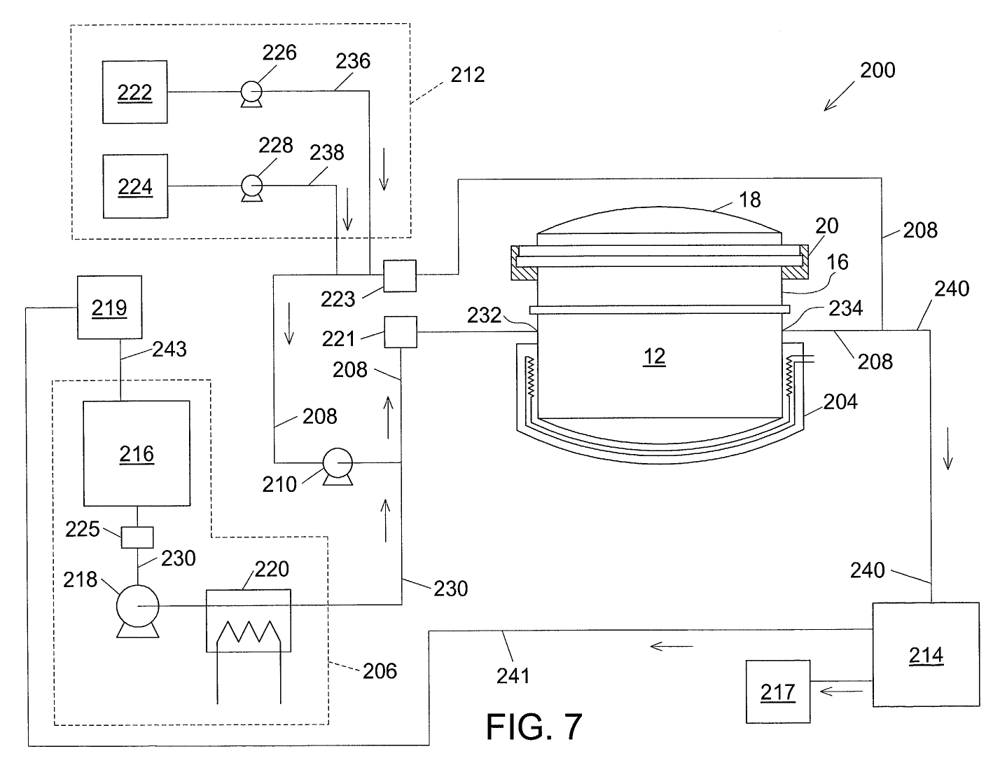

A supercritical processing system of the present invention is illustrated in FIG. 7. The supercritical processing system 200 includes the preferred high pressure processing chamber 12, a pressure chamber heater 204, a carbon dioxide supply arrangement 206, a circulation loop 208, a circulation pump 210, a chemical agent and rinse agent supply arrangement 212, a separating vessel 214, a liquid/solid waste collection vessel 217, and a liquefying/purifying arrangement 219. The carbon dioxide supply arrangement 206 includes a carbon dioxide supply vessel 216, a carbon dioxide pump 218, and a carbon dioxide heater 220. The chemical agent and rinse agent supply arrangement 212 includes a chemical supply vessel 222, a rinse agent supply vessel 224, and first and second high pressure injection pumps, 226 and 228.

The carbon dioxide supply vessel 216 is coupled to the high pressure processing chamber 12 via the carbon dioxide pump 218 and carbon dioxide piping 230. The carbon dioxide piping 230 includes the carbon dioxide heater 220 located between the carbon dioxide pump 218 and the high pressure processing chamber 12. The pressure chamber heater 204 is coupled to the high pressure processing chamber 12. The circulation pump 210 is located on the circulation loop 208. The circulation loop 208 couples to the high pressure processing chamber 12 at a circulation inlet 232 and at a circulation outlet 234. The chemical supply vessel 222 is coupled to the circulation loop 208 via a chemical supply line 236. The rinse agent supply vessel 224 is coupled to the circulation loop 208 via a rinse agent supply line 238. The separating vessel 214 is coupled to the high pressure processing chamber 12 via exhaust gas piping 240. The liquid/solid waste collection vessel 217 is coupled to the separating vessel 214.

The separating vessel 214 is preferably coupled to the liquefying/purifying arrangement 219 via return gas piping 241. The liquefying/purifying arrangement 219 is preferably coupled to the carbon dioxide supply vessel 216 via liquid carbon dioxide piping 243. Alternatively, an off-site location houses the liquefying/purifying arrangement 219, which receives exhaust gas in gas collection vessels and returns liquid carbon dioxide in liquid carbon dioxide vessels.

The pressure chamber heater 204 heats the high pressure processing chamber 12. Preferably, the pressure chamber heater 204 is a heating blanket. Alternatively, the pressure chamber heater is some other type of heater.

Preferably, first and second filters, 221 and 223, are coupled to the circulation loop 208. Preferably, the first filter 221 comprises a fine filter. More preferably, the first filter 221 comprises the fine filter configured to filter 0.05 μm and larger particles. Preferably, the second filter 223 comprises a coarse filter. More preferably, the second filter 223 comprises the coarse filter configured to filter 2-3 μm and larger particles. Preferably, a third filter 225 couples the carbon dioxide supply vessel 216 to the carbon dioxide pump 218. Preferably, the third filter 225 comprises the fine filter. More preferably, the third filter 225 comprises the fine filter configured to filter the 0.05 μm and larger particles.

It will be readily apparent to one skilled in the art that the supercritical processing system 200 includes valving, control electronics, and utility hookups which are typical of supercritical fluid processing systems.

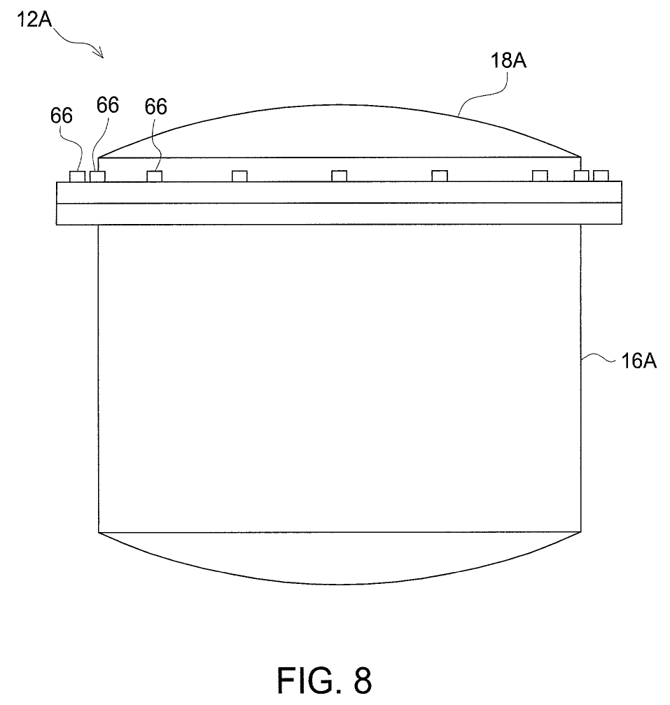

A first alternative high pressure processing chamber of the present invention is illustrated in FIG. 8. The first alternative high pressure processing chamber 12A comprises an alternative chamber housing 16A, an alternative chamber lid 18A, and bolts 66. In the first alternative high pressure chamber, the bolts 66 replace the locking ring 20 (FIG. 3) of the preferred high pressure processing chamber 12.

A second alternative high pressure processing chamber of the present invention comprises the preferred high pressure processing chamber 12 oriented so that an axis of the preferred high pressure processing chamber 12 is horizontal. Thus, in the second alternative high pressure processing chamber, the chamber lid 18 becomes a chamber door.

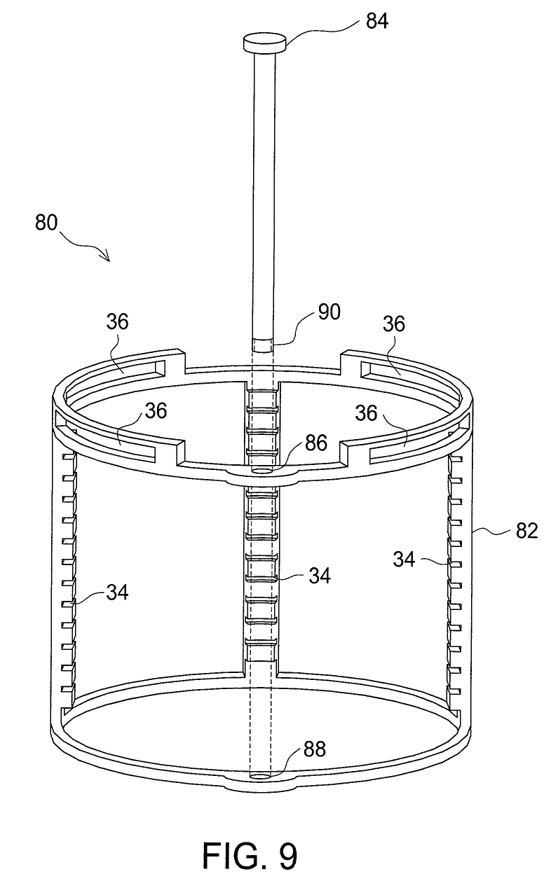

A first alternative cassette of the present invention is illustrated in FIG. 9. The first alternative cassette 80 comprises an alternative cassette frame 82 and an alternative retaining bar 84. In the first alternative cassette, the alternative retaining bar 84 couples to the alternative cassette frame 82 at first and second holes, 86 and 88. Preferably, the alternative retaining bar 84 comprises a threaded region 90 which threads into the second hole 88.

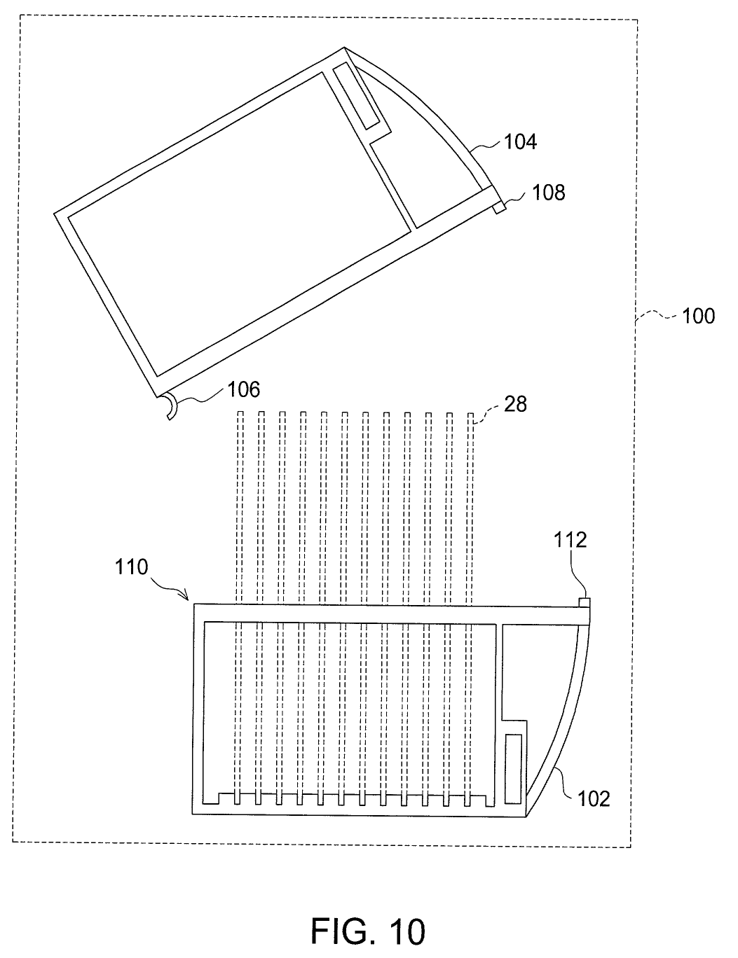

A second alternative cassette of the present invention is illustrated in FIG. 10. The second alternative cassette 100 comprises a wafer holding section 102 and a wafer retaining section 104. The wafer holding section 102 holds the wafers. The wafer retaining section 104 includes a half hinge 106 and a protrusion 108. The wafer holding section 102 comprises a hinge mating region 110 and a protrusion mating feature 112. In operation, the wafer holding section 102 and the wafer retaining section are separate. The wafers 28 are loaded into the wafer retaining section 102, preferably from the FOUP. Then, the half hinge 106 of the wafer retaining section 104 is coupled to the hinge mating region 110 of the wafer holding section 102. Finally, the protrusion 108 of the wafer retaining section 104 is snapped into the protrusion mating feature 112 of the wafer holding section 102.

It will be readily apparent to one skilled in the art that other various modifications may be made to the preferred embodiment without departing from the spirit and scope of the invention as defined by the appended claims.

I claim:

1. A high pressure processing chamber for processing multiple semiconductor substrates comprising:
a. a chamber housing;
b. a first cassette removably coupled to the chamber housing and configured to accommodate at least two semiconductor substrates; and
c. a chamber closure coupled to the chamber housing and configured such that in operation the chamber closure seals with the chamber housing to provide an enclosure for high pressure processing of the semiconductor substrates.

2. The high pressure processing chamber of claim 1 wherein the enclosure formed by the chamber housing and the door provides a supercritical processing environment.

3. The high pressure processing chamber of claim 1 wherein the enclosure formed by the chamber housing and the door provides a high pressure processing environment below supercritical conditions.

4. The high pressure processing chamber of claim 1 wherein at least one of the semiconductor substrates comprises a semiconductor wafer and further wherein the chamber housing and the first cassette are configured to accommodate the semiconductor wafer.

5. The high pressure processing chamber of claim 1 wherein at least one of the semiconductor substrates comprises a semiconductor puck and further wherein the chamber housing and the first cassette are configured to accommodate the semiconductor puck.

6. The high pressure processing chamber of claim 1 wherein at least one of the semiconductor substrates comprises a tray for holding multiple semiconductor devices and further wherein the chamber housing and the first cassette are configured to accommodate the tray.

7. The high pressure processing chamber of claim 1 wherein the first cassette is replaceable with a second cassette.

8. The high pressure processing chamber of claim 7 further comprising a robot such that in operation the robot loads and unloads the first and second cassettes.

9. The high pressure processing chamber of claim 1 wherein the first cassette further comprises an injection nozzle arrangement.

10. The high pressure processing chamber of claim 1 wherein the first cassette further comprises a fluid outlet arrangement.

11. The high pressure processing chamber of claim 1 further comprising an injection nozzle arrangement and a fluid outlet arrangement.

12. The high pressure processing chamber of claim 11 wherein in operation the injection nozzle arrangement and the fluid outlet arrangement provide a process fluid flow in a vicinity of the semiconductor substrates.

13. The high pressure processing chamber of claim 12 wherein the process fluid flow comprises a flow across each of the semiconductor substrates.

14. The high pressure processing chamber of claim 13 wherein the flow across a particular semiconductor substrate comprises a gas injection at a first side of the particular semiconductor substrate and a gas collection at an opposite side of the particular semiconductor substrate.

15. The high pressure processing chamber of claim 1 wherein the chamber housing comprises a proximately cylindrically shaped length having first and second ends.

16. The high pressure processing chamber of claim 15 wherein the chamber housing comprises a dome shaped surface at the first end of the proximately cylindrically shaped length.

17. The high pressure processing chamber of claim 15 wherein the chamber closure seals to the second end of the cylindrically shaped length of the chamber housing.

18. The high pressure processing chamber of claim 15 wherein the chamber closure comprises a dome shaped surface.

19. A high pressure processing chamber for processing multiple semiconductor substrates comprising:
a. a chamber housing;
b. a first cassette removably coupled to the chamber housing and configured to accommodate at least two semiconductor substrates;
c. a chamber closure coupled to the chamber housing and configured such that in operation the chamber closure seals with the chamber housing to provide an enclosure for high pressure processing of the semiconductor substrates; and
d. an injection nozzle arrangement and a fluid outlet arrangement coupled to an interior of the chamber housing such that in operation the injection nozzle arrangement and the fluid outlet arrangement provide a process fluid flow in a vicinity of the semiconductor substrates.

20. A high pressure processing chamber for processing multiple semiconductor substrates comprising:
a. a chamber housing;
b. a first cassette removably coupled to the chamber housing and configured to accommodate at least two semiconductor substrates;
c. a chamber closure coupled to the chamber housing and configured such that in operation the chamber closure seals with the chamber housing to provide an enclosure for high pressure processing of the semiconductor substrates; and
d. a robot coupled to the chamber housing, configured to load the first cassette into the chamber housing prior to the high pressure processing, and configured to unload the first cassette subsequent to the high pressure processing.

21. A high pressure processing chamber for processing multiple semiconductor substrates comprising:
a. a chamber housing;
b. a first cassette removably coupled to the chamber housing and configured to accommodate at least two semiconductor substrates;
c. a chamber closure coupled to the chamber housing and configured such that in operation the chamber closure seals with the chamber housing to provide an enclosure for high pressure processing of the semiconductor substrates;
d. an injection nozzle arrangement and a fluid outlet arrangement coupled to an interior of the chamber housing such that in operation the injection nozzle arrangement and the fluid outlet arrangement provide a process fluid flow in a vicinity of the semiconductor substrates; and
e. a robot coupled to the chamber housing, configured to load the first cassette into the chamber housing prior to the high pressure processing, and configured to unload the first cassette subsequent to the high pressure processing.
